(19) United States
(12) Patent Application Publication
(10) Pub. No.: US 2023/0299113 A1
(43) Pub. Date: Sep. 21, 2023

(54) SOLID-STATE IMAGING DEVICE AND ELECTRONIC DEVICE

(71) Applicant: SONY SEMICONDUCTOR SOLUTIONS CORPORATION, KANAGAWA (JP)

(72) Inventors: SATOKO IIDA, KANAGAWA (JP); YUKI HATTORI, KANAGAWA (JP); YOSHIMITSU NAKASHIMA, KANAGAWA (JP)

(21) Appl. No.: 18/040,166

(22) PCT Filed: Jul. 2, 2021
(86) PCT No.: PCT/JP2021/025185

§ 371 Date: Feb. 1, 2023

(30) Foreign Application Priority Data
Aug. 19, 2020 (JP) 2020-138945

(51) Int. Cl. H01L 27/146

(52) U.S. Cl. CPC H01L 27/14638; H01L 27/14636; H01L 27/14614; H01L 27/14621; H01L 27/1463; H01L 27/14603

(57) ABSTRACT

Provided is a solid-state imaging device that allows high saturation and maximum transfer performance to be achieved. The solid-state imaging device includes a plurality of unit pixels arranged in a two-dimensional array. The plurality of unit pixels each includes a photoelectric conversion unit that photoelectrically converts incident light and a wiring layer stacked on a surface opposite to a light-incident side surface of the photoelectric conversion unit and having a detection node that detects charge stored at the photoelectric conversion unit. In at least some of the plurality of unit pixels, a center of the detection node is coincident with a light receiving center of the photoelectric conversion unit.

### TECHNICAL FIELD

The present disclosure relates to a solid-state imaging device and an electronic device including the solid-state imaging device.

### BACKGROUND ART

For example, according to PTL 1, two pixels having different areas, i.e., a large pixel and a small pixel are arranged in a unit pixel and a light-reducing part is provided on the pixel with the smaller area, so that the pixels have different sensitivities. In this way, the amount of charge to be stored at a charge storage unit of the photoelectric conversion element of the small-area pixel is increased more than the area ratio thereof, and the dynamic range is expanded.

In this example, the transfer electrode positions (detection node electrode positions) of the large-area and small-area pixels are located at the edge of the unit pixel or at the edge of the photoelectric conversion area, such that the photoelectrically converted charge is transferred toward the edges during charge detection. The electrode positions are each at least 10% of the pixel size apart from the optical center.

In recent years, there has been a demand for in-vehicle cameras having a resolution high enough to recognize numerical values on distant signs about 200 m ahead and a frame rate of at least 60 fps. For this reason, the horizontal blanking period (readout time) must be shortened while increasing the number of pixels, and above all, the signal charge transfer time of pixels must be shortened.

### CITATION LIST

### Patent Literature

[PTL 1]
JP 2017-163010A

### SUMMARY

### Technical Problem

In view of the foregoing, when the transfer electrode is provided at the edge of the photoelectric conversion area, it takes time to transfer generated charge, the charge cannot be transferred within desired time. The average transfer time is the worst when the potential is in a no-gradient region and is expressed by “square of distance/diffusion coefficient D”. When the potential is deepened to increase the amount of saturated charge, a potential pocket is created in the potential gradient of the transfer path and the charge is more likely to be trapped. Depending on the height and temperature of the pocket, it also takes time for the charge to get out of there, and therefore it is disadvantageous to provide the transfer electrode at the edge in view of maximizing the saturation and transfer performance.

In the structure including the large and small pixels, the structure for creating a potential gradient toward the transfer gate (the shape of the photoelectric conversion area) is not symmetrical between large and small pixels, resulting in transfer defects and transfer time delays because of asymmetry in charge transfer, and the sensitivity ratio and sensitivity shading between large and small pixels prevent correlation to the light quantity and wavelength from being constant. Since the outputs of large and small pixels are finally synthesized by multiplying a sensitivity ratio gain, the output linearity with respect to the light quantity must be constant.

With the foregoing in view, it is an object of the present disclosure to provide a solid-state imaging device and an electronic device that allow high saturation and maximum transfer performance to be achieved.

### Solution to Problem

A solid-state imaging device according to an aspect of the present disclosure includes a plurality of unit pixels arranged in a two-dimensional array, the plurality of unit pixels each includes a photoelectric conversion unit that photoelectrically converts incident light and a wiring layer stacked on a surface opposite to a light-incident side surface of the photoelectric conversion unit and having a detection node that detects charge stored at the photoelectric conversion unit, and in at least some of the plurality of unit pixels, a center of the detection node is substantially coincident with a light receiving center of the photoelectric conversion unit.

An electronic device according to another aspect of the present disclosure includes a solid-state imaging device, the solid-state imaging device includes a plurality of unit pixels arranged in a two-dimensional array, the plurality of unit pixels each includes a photoelectric conversion unit that photoelectrically converts incident light and a wiring layer stacked on a surface opposite to a light-incident side surface of the photoelectric conversion unit and having a detection node that detects charge stored at the photoelectric conversion unit, and in at least some of the plurality of unit pixels, and a center of the detection node is coincident with a light receiving center of the photoelectric conversion unit.

### BRIEF DESCRIPTION OF DRAWINGS

FIG. 1 is a schematic diagram of the overall structure of a solid-state imaging device according to a first embodiment of the present disclosure.

FIG. 2 is a plan view of a pixel region in the solid-state imaging device according to the first embodiment of the present disclosure.

FIG. 3 is an equivalent circuit diagram of a unit pixel according to the first embodiment of the present disclosure.

FIG. 4 is a plan view of an arrangement of pixel transistors in large-area and small-area pixels according to the first embodiment of the present disclosure.

FIG. 5 is a vertical cross section of the large-area pixel according to the first embodiment of the present disclosure taken between arrows A and B.

FIG. 6 is a plan view of an arrangement of pixel transistors in large-area and small-area pixels in a solid-state imaging device according to a second embodiment of the present disclosure.

FIG. 7 is a vertical cross-section of a large-area pixel according to the second embodiment of the present disclosure taken between arrows A1 and B1.

FIG. 8 is a plan view of an arrangement of pixel transistors in large-area and small-area pixels in a solid-state imaging device according to a third embodiment of the present disclosure.

FIG. 9 is a vertical cross-section of a large-area pixel according to the third embodiment of the present disclosure taken between arrows A2 and B2.

FIG. 10 is a plan view of an arrangement of pixel transistors in large-area and small-area pixels in a solid-state imaging device according to a fourth embodiment of the present disclosure.

FIG. 11 is a vertical cross-section of a small-area pixel according to the fourth embodiment of the present disclosure taken between arrows A3 and B3.

FIG. 12 is a circuit diagram of an equivalent circuit of a unit pixel according to a fifth embodiment of the present disclosure.

FIG. 13 is a plan view of an arrangement of pixel transistors in large-area and small-area pixels according to the fifth embodiment of the present disclosure.

FIG. 14 is a vertical cross-section of a small-area pixel according to the fifth embodiment of the present disclosure taken between arrows A4 and B4.

FIG. 15 is a vertical cross section of a small-area pixel according to a sixth embodiment of the present disclosure.

FIG. 16 is a plan view of an arrangement of pixel transistors in large-area and small-area pixels in a solid-state imaging device according to a seventh embodiment of the present disclosure.

FIG. 17 is a vertical cross section of a large-area pixel according to the seventh embodiment of the present disclosure taken between arrows A5 and B5.

FIG. 18 is a plan view of an arrangement of pixel transistors in large-area and small-area pixels in a solid-state imaging device according to an eighth embodiment of the present disclosure.

FIG. 19 is a vertical cross section of a small-area pixel according to the eighth embodiment of the present disclosure taken between arrows A6 and B6.

FIG. 20 is a plan view of an arrangement of pixel transistors in large-area and small-area pixels in a solid-state imaging device according to a ninth embodiment of the present disclosure.

FIG. 21 is a vertical cross section of large-area and small-area pixels according to the ninth embodiment of the present disclosure taken between arrows A7 and B7.

FIG. 22 is a plan view of RGGB type large-area and small-area pixels according to a tenth embodiment of the present disclosure.

FIG. 23 is a plan view of RCCB type large-area and small-area pixels according to the tenth embodiment of the present disclosure.

FIG. 24 is a plan view of RYYCy type large-area and small-area pixels according to the tenth embodiment of the present disclosure.

FIG. 25 is a plan view of RCCC type large-area and small-area pixel according to the tenth embodiment of the present disclosure.

FIG. 26 is a plan view of RGB/BLK type large-area and small-area pixels according to the tenth embodiment of the present disclosure.

FIG. 27 is a plan view of RGB/IR type large-area and small-area pixels according to the tenth embodiment of the present disclosure.

FIG. 28 is a plan view of RGB/polarization type large-area and small-area pixels according to the tenth embodiment of the present disclosure.

FIG. 29 is a plan view of RGB/polarization/IR type large-area and small-area pixels according to the tenth embodiment of the present disclosure.

FIG. 30 is a schematic diagram of an electronic device according to an eleventh embodiment of the present disclosure.

### DESCRIPTION OF EMBODIMENTS

Embodiments of the present disclosure will be described with reference to the drawings. In the drawings to be referred to in the following description, the same or similar portions will be denoted by the same or similar reference characters and their description will not be repeated. It should be noted however that the drawings are schematic, and the relationships between thicknesses and two-dimensional sizes and the ratios of thicknesses of devices or members may not be true to reality. Therefore, specific thicknesses and dimensions should be determined in consideration of the following description. In addition, it is understood that some portions have different dimensional relationships and ratios among drawings.

Herein, a “first conductivity type” refers to one of p-type and n-type, and a “second conductivity type” refers to one of p-type and n-type that is different from the “first conductivity type”. The semiconductor regions with “+” and “−” suffixed to “n” and “p” indicate that the semiconductor regions have relatively higher and lower impurity densities than semiconductor regions without “+” and “−”. However, it does not necessarily mean that semiconductor regions with the same character “n” have exactly the same impurity density.

In addition, the directions defined such as upward and downward in the following description are merely definitions provided for the sake of brevity and are not intended to limit technical ideas in the present disclosure. For example, it should be understood that when an object is rotated by 90 degrees and observed, the up-down direction is interpreted as the left-right direction, and when an object is rotated by 180 degrees and observed, the up and down positions are reversed. The advantageous effects described herein are merely exemplary and are not restrictive, and other advantageous effects may be produced.

### First Embodiment

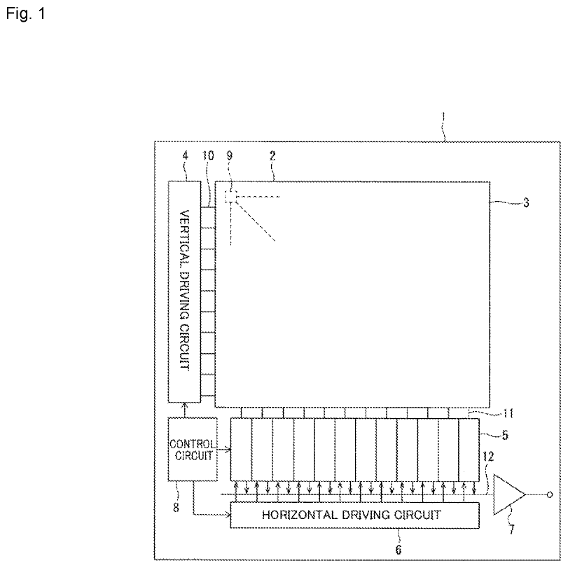

(Overall Configuration of Solid-state Imaging Device) A solid-state imaging device 1 according to a first embodiment of the present disclosure will be described. FIG. 1 is a schematic diagram of the overall solid-state imaging device 1 according to the first embodiment of the present disclosure.

The solid-state imaging device 1 in FIG. 1 is a backside-illumination type complementary metal oxide semiconductor (CMOS) image sensor. The solid-state imaging device 1 takes in image light from an object through an optical lens, converts the light quantity of the incident light of an image formed on an imaging surface into an electrical signal on a pixel-basis, and outputs the electrical signal as a pixel signal.

As shown in FIG. 1, the solid-state imaging device 1 according to the first embodiment includes a substrate 2, a pixel region 3, a vertical driving circuit 4, column signal processing circuits 5, a horizontal driving circuit 6, an output circuit 7, and a control circuit 8.

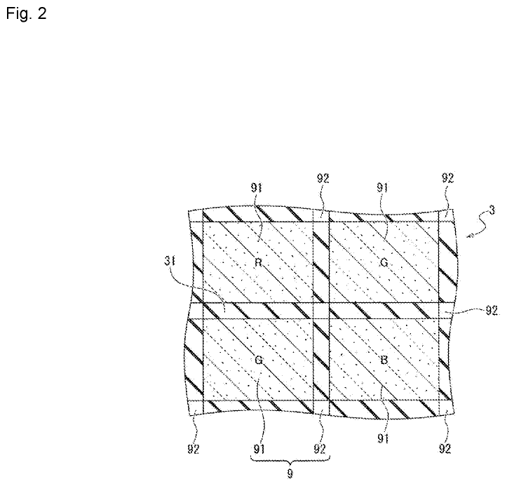

The pixel region 3 includes a plurality of unit pixels 9 arranged regularly in a two-dimensional array on the substrate 2. The unit pixel 9 includes a large-area pixel 91 and a small-area pixel 92 shown in FIG. 2.

The vertical driving circuit 4 may include a shift register, selects a desired pixel driving wiring 10, supplies a pulse for driving the unit pixel 9 to the selected pixel driving wiring 10, and drives unit pixels 9 on a row-basis. More specifically, the vertical driving circuit 4 selectively scans the unit pixels 9 in the pixel region 3 sequentially in the vertical direction on a row-basis, and supplies pixel signals based on signal charge generated according to the quantities of received light in the photoelectric conversion units of the unit pixels 9 to the column signal processing circuits 5 through vertical signal lines 11.

For example, the column signal processing circuit 5 is provided for each of the columns of unit pixels 9 to perform signal processing such as noise removal to signals output from a row of unit pixels 9 on a pixel column basis. For example, the column signal processing circuit 5 performs signal processing such as correlated double sampling (CDS) for removing pixel-specific fixed pattern noise and analog-digital (AD) conversion.

The horizontal driving circuit 6 may include a shift register, sequentially outputs horizontal scanning pulses to the column signal processing circuits 5 to select each of the column signal processing circuits 5 in order, and outputs a pixel signal having been subjected to signal processing to the horizontal signal line 12 from each of the column signal processing circuits 5.

The output circuit 7 performs signal processing on the pixel signals sequentially supplied from the column signal processing circuits 5 through the horizontal signal line 12, and outputs resultant pixel signals. Examples of the signal processing include buffering, black level adjustment, column variation correction, and various digital signal processing.

The control circuit 8 generates a clock signal or a control signal as a reference for example for operation of the vertical driving circuit 4, the column signal processing circuit 5, and the horizontal driving circuit 6 on the basis of a vertical synchronization signal, a horizontal synchronization signal, and a master clock signal. The control circuit 8 also outputs the generated clock signal or control signal for example to the vertical driving circuit 4, the column signal processing circuit 5, and the horizontal driving circuit 6.

FIG. 2 is a plan view of the pixel region 3 in the solid-state imaging device 1 shown in FIG. 1. As shown in FIG. 2, the unit pixel 9 has a sub-pixel structure including a large-area pixel 91 and a small-area pixel 92 and has multiple large-area and small-area pixels 91 and 92 arranged in a mosaic pattern. As schematically shown in FIG. 2, the large-area pixel 91 for red is labeled “R”, the large-area pixel 91 for blue is labeled “B”, and the large-area pixel 91 for green is labeled “G”. The arrangement pattern of the large-area pixels 91 and the small-area pixels 92 is not limited to that in FIG. 2, and the pixels may be arranged in various patterns.

In FIG. 2, the large-area pixels 91 and the small-area pixels 92 are arranged with equal pitch in the row and column directions. The large-area pixel 91 and small-area pixel 92 are electrically isolated by an inter-pixel light-shielding part (RDTI) 31. The RDTI 31 is formed in a matrix pattern to surround each large-area pixel 91 and each small-area pixel 92.

(Equivalent Circuit of Unit Pixel)

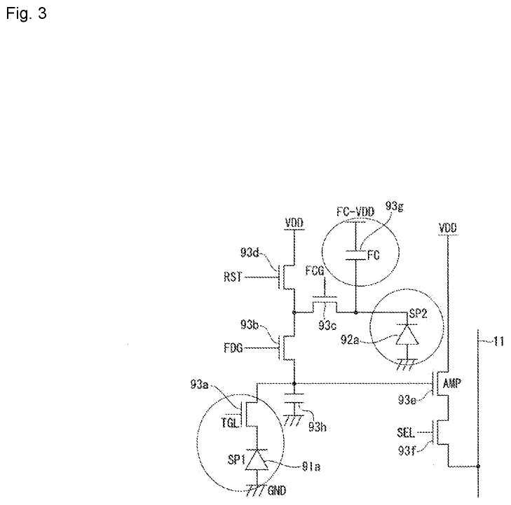

FIG. 3 illustrates an equivalent circuit of the unit pixel 9.

The unit pixel 9 includes a photodiode (SP1) 91a for the large-area pixel 91, a photodiode (SP2) 92a for the small-area pixel 92, a transfer transistor (TGL) 93a, conversion efficiency adjustment transistors (FDG and FCG) 93b and 93c, a reset transistor (RST) 93d, an amplification transistor (AMP) 93e, a selection transistor (SEL) 93f, and a charge storage capacitor unit 93g. The transfer transistor (TGL) 93a, the conversion efficiency adjustment transistors (FDG and FCG) 93b and 93c, the reset transistor (RST) 93d, the amplification transistor 93e, and the selection transistor (SEL) 93f is a pixel transistor, and may be MOS transistors.

The photodiode 91a for the large-area pixel 91 constitutes a photoelectric conversion unit that performs photoelectric conversion on incident light. The photodiode 91a has its anode grounded. The photodiode 91a has its cathode connected to the source of the transfer transistor 93a.

The transfer transistor 93a has its drain connected to the charge storage unit 93h which is made of a floating diffusion region. The transfer transistor 93a transfers charge from the photodiode 91a to the charge storage unit 93h in response to a transfer signal applied to the gate.

The charge storage unit 93h stores the charge transferred from the photodiode 91a through the transfer transistor 93a. The potential of the charge storage unit 93h is modulated according to the amount of charge stored at the charge storage unit 93h. The source of the conversion efficiency adjustment transistor 93b is connected to the charge storage unit 93h. The conversion efficiency adjustment transistor 93b has its drain connected to the sources of the conversion efficiency adjustment transistor 93c and the reset transistor 93d. The conversion efficiency adjustment transistor 93b adjusts the charge conversion efficiency in response to a conversion efficiency adjustment signal applied to the gate.

Meanwhile, the photodiode 92a for the small-area pixel 92 constitutes a photoelectric conversion unit that converts incident light into a photoelectric signal. The photodiode 92a has its anode grounded. The photodiode 92a has its cathode connected to the charge storage capacitor unit 93g. A power supply potential (FC-VDD) is applied to the charge storage capacitor unit 93g. The drain of the conversion efficiency adjustment transistor 93c is connected to the cathode of the photodiode 92a and the charge storage capacitor unit 93g.

When the conversion efficiency adjustment transistors 93b and 93c are off, the charge storage capacitor unit 93g stores charge generated from the photodiode 92a. In response to a conversion efficiency adjustment signal applied to the gates of the conversion efficiency adjustment transistor 93b and 93c, the charge generated from the photodiode 92a and the charge stored at the charge storage capacitor unit 93g are transferred to the charge storage unit 93h.

A power supply potential (VDD) is applied to the drain of the reset transistor 93d. The reset transistor 93d initializes (resets) the charge stored at the charge storage capacitor unit 93g and the charge stored at the charge storage unit 93h in response to a reset signal applied to the gate.

The charge storage unit 93h and the drain of the transfer transistor 93a are connected with the gate of the amplification transistor 93e. The amplification transistor 93e has its drain connected with the source of the selection transistor 93f. The power supply potential (VDD) is applied to the source of the amplification transistor 93e. The amplification transistor 93e amplifies the potential of the charge storage unit 93h.

The selection transistor 93f has its drain connected to the vertical signal line 11. The selection transistor 93f selects a unit pixel 9 in response to a selection signal. When the unit pixel 9 is selected, a pixel signal corresponding to the potential amplified by the amplification transistor 93e is output through the vertical signal line 11.

(Arrangement of Pixel Transistors)

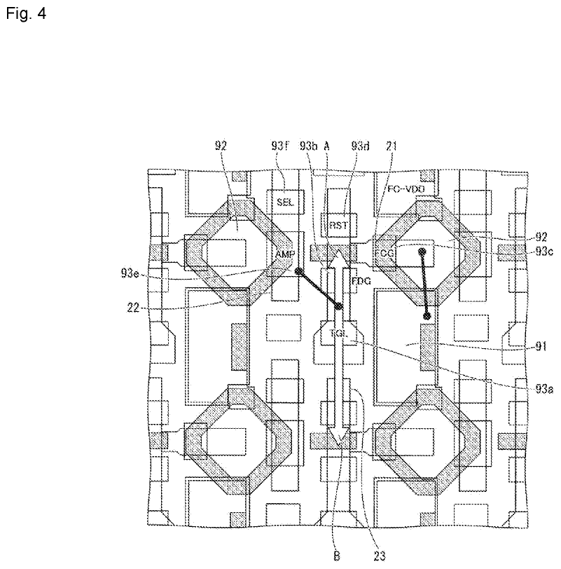

FIG. 4 is a plan view of an arrangement of pixel transistors in the large-area pixel 91 and the small-area pixel 92.

The transfer transistor (TGL) 93a, the conversion efficiency adjustment transistors (FDG and FCG) 93b and 93c, and the reset transistor (RST) 93d are provided in the wiring 21. The amplification transistor (AMP) 93e and the selection transistor (SEL) 93f are provided in the wiring 22. The wiring 21 and the amplification transistor (AMP) 93e are connected for example by a bonding wire. The wiring 22 and the wiring 23 are electrically disconnected.

(Sectional Structure of Unit Pixel)

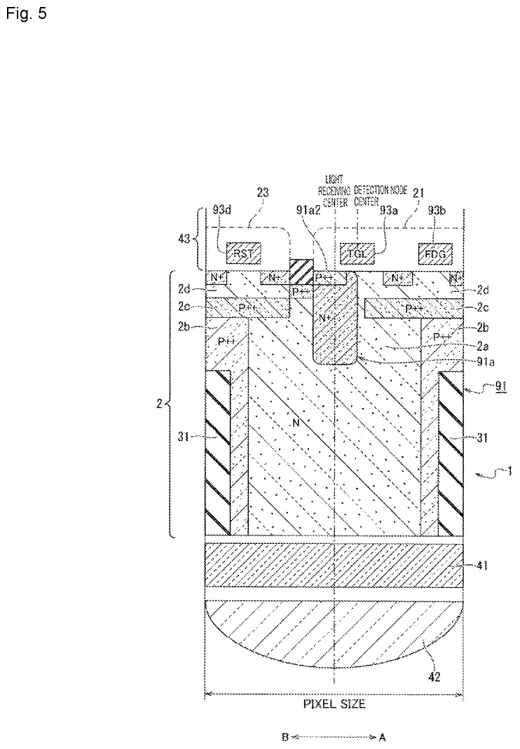

FIG. 5 is a vertical cross section of the large-area pixel 91 along A-B in FIG. 4. Hereinafter, the surface of each member of the solid-state imaging device 1 on the light-incident surface side (the lower side in FIG. 5) will be referred to as the “backside surface”, and the surface of each member of the solid-state imaging device 1 on the side (the upper side in FIG. 5) opposite to the light-incident surface side will be referred to as the “front surface”.

As shown in FIG. 5, in the large-area pixel 91, a photodiode 91a is formed on the substrate 2. A color filter 41 and an on-chip lens 42 are arranged in this order on the backside surface of the semiconductor substrate 2. The wiring layer 43 is stacked on the front surface of the substrate 2.

The substrate 2 may be a semiconductor substrate made of silicon (Si). The photodiode 91a is made by a pn junction between an n-type semiconductor region 91a1 and a p-type semiconductor region 91a2 formed on the front surface side of the substrate 2. In the photodiode 91a, signal charge corresponding to the quantity of incident light through an n-type semiconductor region 2a is generated, and the generated signal charge is stored at the n-type semiconductor region 91a1. The electrons attributable to dark current generated at the interface of the substrate 2 are absorbed by the holes that are the majority carriers of a p-type semiconductor region 2b formed in the depth-wise direction from the backside surface of the substrate 2 and a p-type semiconductor region 2c formed on the front surface, so that the dark current is reduced.

The large-area pixel 91 is electrically isolated by the RDTI 31 formed in the P-type semiconductor region 2b. As shown in FIG. 5, the RDTI 31 is formed in the depth-wise direction from the backside surface of the substrate 2. The RDTI 31 has an insulating film embedded therein for improving the light-shielding performance. The on-chip lens 42 collects emitted light and lets the collected light efficiently enter the photodiode 91a in the substrate 2 through the color filter 41. The on-chip lens 42 can be made of an insulating material that does not have a light absorbing property.

The color filter 41 is formed corresponding to the wavelength of light desired to be received by each unit pixel 9. The color filter 41 transmits light in an arbitrary light wavelength, and lets the transmitted light enter the photodiode 91a in the substrate 2.

The wiring layer 43 is formed on the front surface side of the substrate 2 and includes pixel transistors (among which only the transfer transistor 93a, the conversion efficiency adjustment transistor 93b, and the reset transistor 93d are shown in FIG. 5) and the wirings 21 and 23. The wiring layer 43 is provided with the charge storage unit 93h made of a floating diffusion region.

In the solid-state imaging device 1 having the above configuration, light is emitted from the backside surface of the substrate 2, the emitted light is transmitted through the on-chip lens 42 and the color filter 41, and the transmitted light is photoelectrically converted by the photodiode 91a, so that signal charge is generated. Then, the generated signal charge is output as a pixel signal on the vertical signal line 11 shown in FIG. 1 formed by the wirings 21, 22, and 23 through the pixel transistor formed in the wiring layer 43.

According to the first embodiment, the charge storage capacitor unit 93g is not a storage layer inside the substrate 2, but is placed in the wiring layer 43. A high density p type is implanted to the boundary between the laminated layers to isolate the layers. In this way, the photoelectric conversion area can be maximized rather than planar layout arrangement.

According to the first embodiment, the light receiving center of the large-area pixel 91 is the center of the area surrounded by the RDTI 31. The detection node center refers to the center of the gate electrode of the transfer transistor 93a. The detection node detects charge stored at the photodiode 91a.

In this example, the position of the light receiving center of and the position of the center of the detection node are substantially coincident. Here, the wording “substantially coincident” refers to the case in which the normal passing through the center of the light-receiving surface of the large-area pixel 91 and the normal passing through the center of the detection node are perfectly coincident and also other cases in which these lines are considered substantially coincident. There may be discrepancies that do not affect the accuracy of uniformity. For example, The range with a discrepancy within 10% of the pixel size can be called substantial coincidence. For example, if the pixel size is 3 μm, and a detection node center is within a distance of 0.3 μm from the light receiving center, the state may be a substantial coincidence.

Note that in order to provide an FD (floating diffusion) region and the pixel transistors adjacent to the transfer gate electrode of the transfer transistor 93a provided at the center, a high density p-type semiconductor region 2c must be provided to isolate the n-type semiconductor region 2a in the underlying photoelectric conversion area and the n-type semiconductor region 2d of the FD diffusion layer. It is essential to place the FD diffusion layer near the center regardless of the presence or absence of FC capacitance.

### Function and Effect According to First Embodiment

As described above, according to the first embodiment, the moment the transfer transistor 93a as the detection node is turned on, charge generated by photoelectric conversion by the photodiode 91a is subjected to an electric field corresponding to the power supply voltage in the vicinity of the transfer transistor 93a, and this allows the transfer to be efficient in the shortest possible time since the position of the gate electrode of transfer transistor 93a is at the same position as the light receiving center of the photodiode 91a.

According to the first embodiment, the potential is deepest is the center of the photoelectric conversion area, i.e., directly below the gate electrode of the transfer transistor 93a. The charge needs only move substantially in the vertical direction from the deepest point and does not have to move horizontally, which makes it difficult for pockets to form in the potential gradient.

Therefore, according to the first embodiment, high saturation and maximum transfer performance can be achieved by matching the center of light reception and the center of transfer, and sensitivity shading can be suppressed, coloration can be reduced, and the SN ratio can be improved in the structure including large-area and small-area pixels.

### Second Embodiment

Next, a second embodiment will be described. The second embodiment is a modification of the first embodiment.

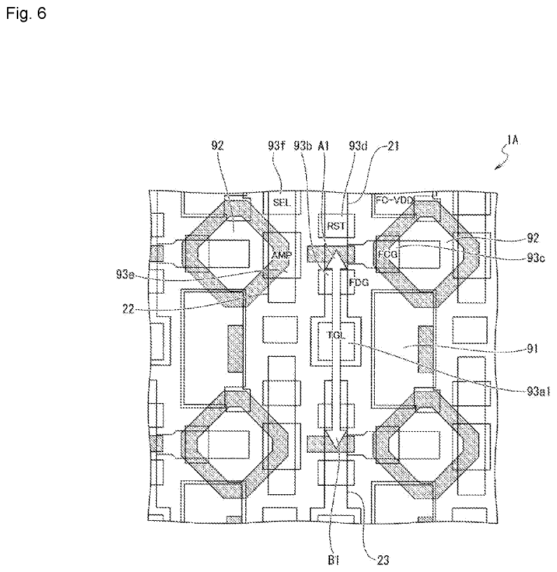

FIG. 6 is a plan view of an arrangement of pixel transistors in the large-area pixel 91 and the small-area pixel 92 in a solid-state imaging device 1A according to the second embodiment. In FIG. 6, the same parts as those in FIG. 4 are denoted with the same characters, and detailed description thereof will not be provided.

According to the second embodiment, a planar type transfer transistor 93a1 is used.

(Sectional Structure of Unit Pixel)

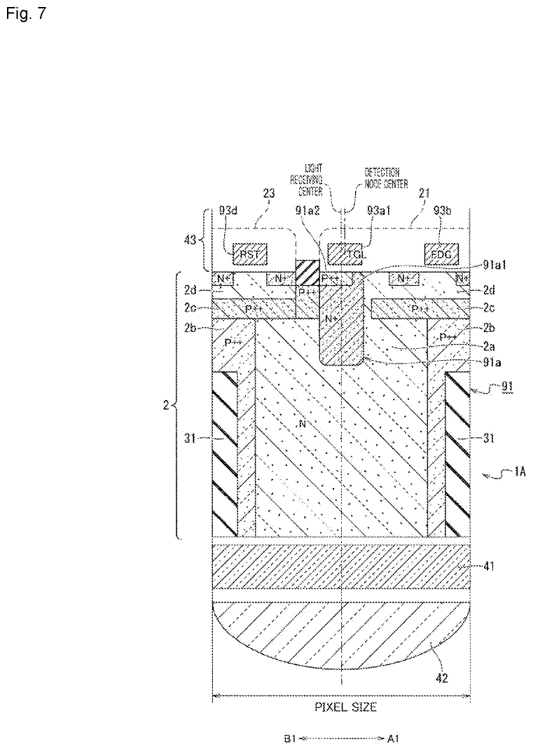

FIG. 7 is a vertical cross section of the large-area pixel 91 in FIG. 6 taken between arrows A1 and B1. In FIG. 7, the same parts as those in FIG. 5 are denoted with the same characters, and detailed description thereof will not be provided. According to the second embodiment, the detection node center is the center of the gate electrode of the planar type transfer transistor 93a1. In this example, the position of the light receiving center and the position of the detection node center are even more coincident than the case according to the first embodiment.

### Function and Effect According to Second Embodiment

As in the foregoing, according to the second embodiment, the center of the gate electrode of the transfer transistor 93a1 is further coincide with the light receiving center of the photodiode 91a, so that the transfer time can be shortened.

### Third Embodiment

Next, a third embodiment will be described. The third embodiment is a modification of the first embodiment.

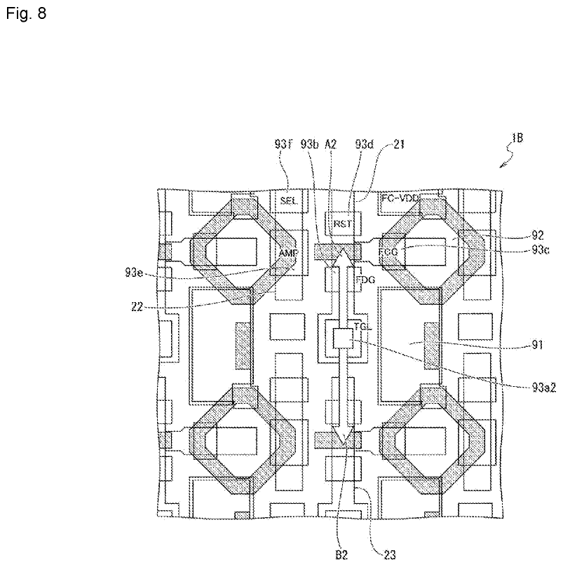

FIG. 8 is a plan view of an arrangement of pixel transistors in large-area and small-area pixels 91 and 92 in a solid-state imaging device 1B according to the third embodiment. In FIG. 8, the same parts as those in FIG. 4 are denoted with the same characters, and detailed description thereof will not be provided. According to the third embodiment, the vertical type transistor is used for the transfer transistor 93a2.

(Sectional Structure of Unit Pixel)

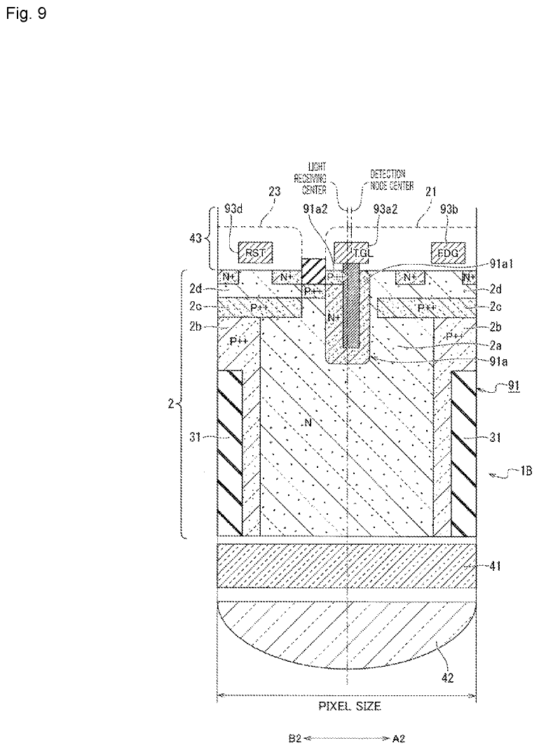

FIG. 9 is a vertical cross section of the large-area pixel 91 in FIG. 8 taken between arrows A2 and B2. In FIG. 9, the same parts as those in FIG. 5 are denoted with the same characters, and detailed description thereof will not be provided.

According to the third embodiment, the detection node center is at the center of the gate electrode of the vertical transfer transistor 93a2. In this example, the position of the light receiving center and the position of the detection node center are even more coincident than the case according to the first embodiment.

### Function and Effect According to Third Embodiment

As described above, according to the third embodiment, while the center of the gate electrode of the transfer transistor 93a2 is further coincident with the light receiving center of the photodiode 91a, the transfer in the depth-wise direction is further facilitated and the transfer time can be shortened.

### Fourth Embodiment

Next, a fourth embodiment will be described. The fourth embodiment is a modification of the first embodiment.

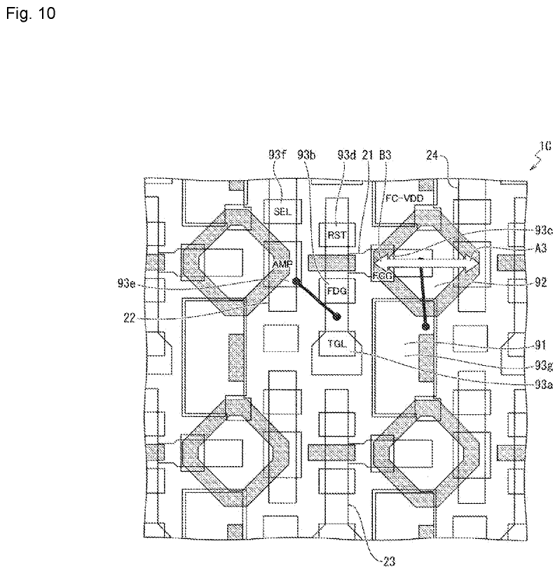

FIG. 10 is a plan view of an arrangement of pixel transistors in large-area and small-area pixels 91 and 92 in a solid-state imaging device 1C according to the fourth embodiment. In FIG. 10, the same parts as those in FIG. 4 are denoted with the same characters, and detailed description thereof will not be provided. According to the fourth embodiment, in the small-area pixel 92, the detection node center is a direct-connection type that makes direct contact with the diffusion layer.

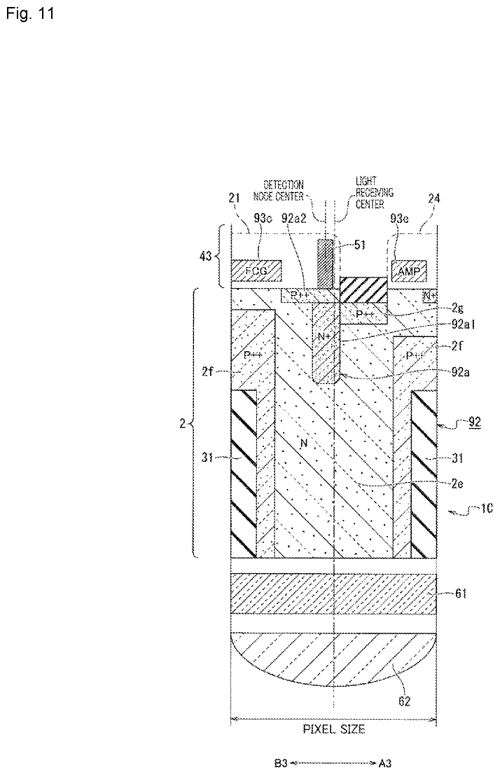

(Sectional Structure of Unit Pixel) FIG. 11 is a vertical cross section of the small-area pixel 92 in FIG. 10 taken between arrows A3 and B3. In FIG. 11, the same parts as those in FIG. 5 are denoted with the same characters, and detailed description thereof will not be provided.

As shown in FIG. 11, the small-area pixel 92 has a photodiode 92a formed on the substrate 2. A color filter 61 and an on-chip lens 62 are arranged in this order on the backside surface of the semiconductor substrate 2. The wiring layer 43 is stacked on the front surface of the substrate 2.

The photodiode 92a includes a pn junction between an n-type semiconductor region 92a1 and a p-type semiconductor region 92a2 formed on the front surface side of the substrate 2. In the photodiode 92a, signal charge corresponding to the quantity of incident light through an n-type semiconductor region 2e is generated, and the generated signal charge is stored at the n-type semiconductor region 92a1. The electrons attributable to dark current generated at the interface of the substrate 2 are absorbed by the holes that are the majority carriers of a p-type semiconductor region 2f formed in the depth-wise direction from the backside surface of the substrate 2 and a p-type semiconductor region 2g formed on the front surface, so that the dark current is reduced.

The small-area pixel 92 is electrically isolated by an RDTI 31 formed in the p-type semiconductor region 2f. As shown in FIG. 11, the RDTI 31 is formed in the depth-wise direction from the backside surface of the substrate 2. The RDTI 31 has an insulating film embedded therein for improving the light-shielding performance.

The on-chip lens 62 collects emitted light and lets the collected light efficiently enter the photodiode 92a in the substrate 2 through the color filter 61.

The wiring layer 43 is formed on the front surface side of the substrate 2 and includes pixel transistors (among which only the conversion efficiency adjustment transistor 93b and the amplification transistor 93e are shown in FIG. 11) and the wirings 21 and 24.

According to the fourth embodiment, metal 51 connected to the photodiode 92a as a detection node center is arranged in the wiring layer 43. In this case, the detection node center is a direct-connection type that makes direct contact with the diffusion layer. Thus, the POLY electrode does not have to be used.

### Function and Effect According to Fourth Embodiment

As in the foregoing, according to the fourth embodiment, the detection node center is coincident with the light receiving center of the photodiode 92a, so that the transfer time can be shortened.

### Fifth Embodiment

Next, a fifth embodiment will be described. The fifth embodiment is a modification of the first embodiment.

<Equivalent Circuit of Unit Pixel>

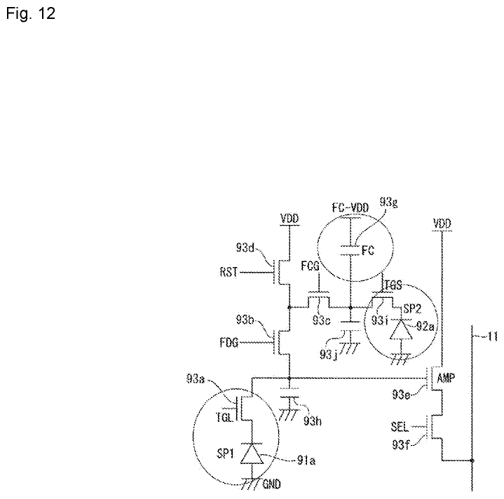

FIG. 12 is an equivalent circuit diagram of a unit pixel 9 according to the fifth embodiment. In FIG. 12, the same parts as those in FIG. 3 are denoted with the same reference numerals, and detailed description thereof will not be provided. According to the fifth embodiment, a transfer transistor (TGS) 93i is interposed between the photodiode (SP2) 92a of the small-area pixel 92 and the charge storage capacitor unit (FC) 93g and the conversion efficiency adjustment transistor (FCG) 93c. The photodiode 92a has its cathode connected to the source of the transfer transistor 93i.

The transfer transistor 93i has its drain connected to the charge storage unit 93j which is made of a floating diffusion region. The transfer transistor 93i transfers charge from the photodiode 92a to the charge storage unit 93j in response to a transfer signal applied to the gate.

(Arrangement of Pixel Transistors)

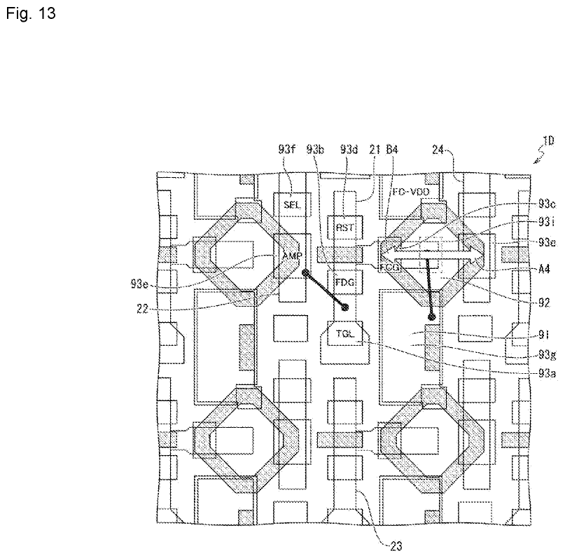

FIG. 13 is a plan view of an arrangement of pixel transistors in the large-area and small-area pixels 91 and 92 according to the fifth embodiment.

The transfer transistor (TGL) 93a, the conversion efficiency adjustment transistors (FDG and FCG) 93b and 93c, the reset transistor (RST) 93d, and the transfer transistor (TGS) 93i are provided in the wiring 21. The amplification transistor (AMP) 93e and the selection transistor (SEL) 93f are provided in the wiring 22. The wiring 21 and the amplifying transistor (AMP) 93e are connected to by a bonding wire. The amplification transistor (AMP) 93e is also provided in the wiring 24.

(Sectional Structure of Unit Pixel)

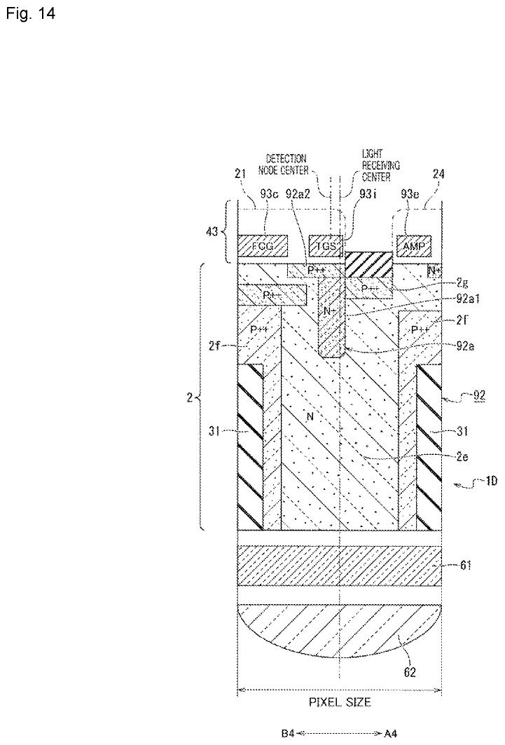

FIG. 14 is a vertical cross section of the small-area pixel 92 in FIG. 13 taken between arrows A4 and B4. In FIG. 14, the same parts as those in FIG. 11 are denoted with the same characters, and detailed description thereof will not be provided. In the solid-state imaging device 1D according to the fifth embodiment, the transfer transistor (TGS) 93i connected to the photodiode 92a as the detection node center is provided in the wiring layer 43.

### Function and Effect According to Fifth Embodiment

As in the foregoing, according to the fifth embodiment, the gate electrode of the transfer transistor 93i is coincident with the light receiving center of the photodiode 92a, so that the transfer time can be shortened.

### Sixth Embodiment

Next, a sixth embodiment will be described. The sixth embodiment is a modification of the fifth embodiment.

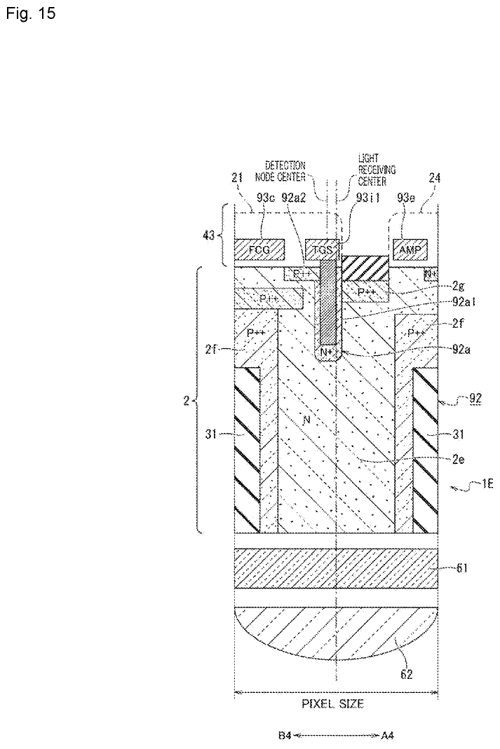

FIG. 15 is a vertical cross section of the small-area pixel 92 in FIG. 13 according to the sixth embodiment taken between arrows A4 and B4. In FIG. 15, the same parts as those in FIG. 14 are denoted with the same reference numerals, and detailed description thereof will not be provided.

In the solid-state imaging device 1E according to the sixth embodiment, the transfer transistor 93i1 is a vertical transistor with a vertigal gate (VG). The detection node center is at the center of the gate electrode of the transfer transistor 93i1 which is a vertical transistor. In this case, the position of the light receiving center and the position of the detection node center are even more coincident than the case according to the fifth embodiment.

### Function and Effect According to Sixth Embodiment

As in the foregoing, according to the sixth embodiment, while the center of the gate electrode of the transfer transistor 93i1 is more coincident with the light receiving center of the photodiode 92a, the transfer in the depth-wise direction is further facilitated, so that the transfer time can be shortened.

### Seventh Embodiment

Next, a seventh embodiment will be described. The seventh embodiment is a modification of the first embodiment.

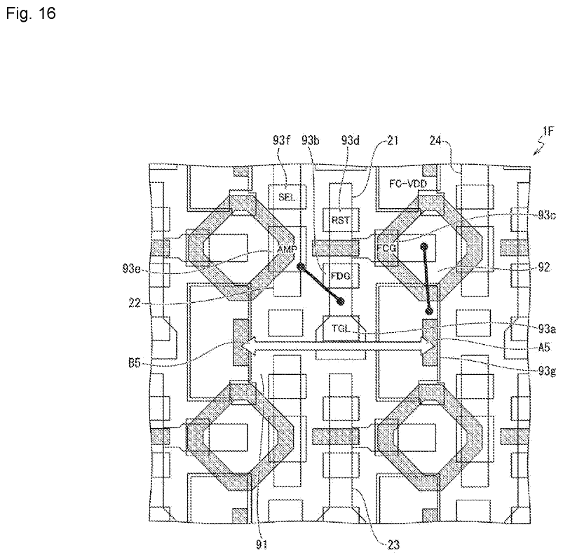

FIG. 16 is a plan view of an arrangement of pixel transistors in large-area and small-area pixels 91 and 92 in a solid-state imaging device 1F according to the seventh embodiment. In FIG. 16, the same parts as those in FIG. 4 are denoted with the same characters, and detailed description thereof will not be provided. According to the seventh embodiment, the large-area pixel 91 is taken between arrows A5 and B5 which is different from the first embodiment.

(Sectional Structure of Unit Pixel)

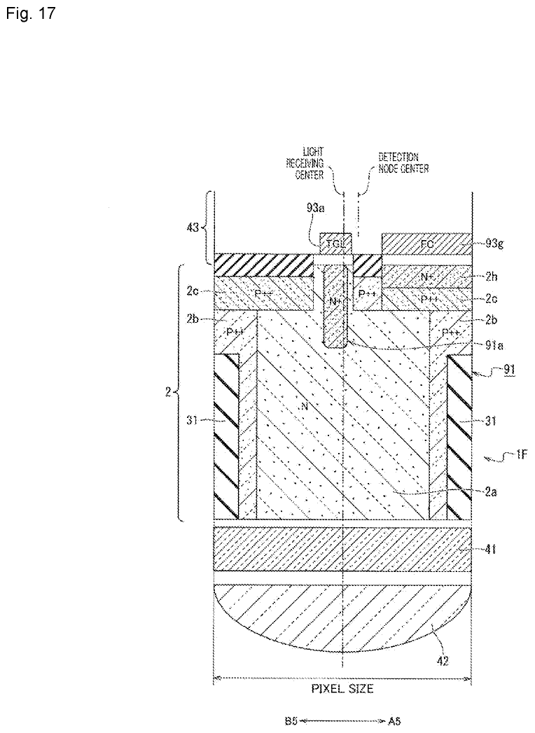

FIG. 17 is a vertical cross section of the large-area pixel 91 in FIG. 16 taken between arrows A5 and B5. In FIG. 17, the same parts as those in FIG. 5 are denoted with the same characters, and detailed description thereof will not be provided. As shown in FIG. 17, the charge storage capacitor unit 93g as an intra-pixel capacitor is located in the wiring layer 43 at the upper part (the backside surface) of the photoelectric conversion region including a p-type semiconductor region 2c and an n-type semiconductor region 2h, so that the layout may be more area-efficient than a two-dimensional arrangement.

### Eighth Embodiment

Next, an eighth embodiment will be described. The eighth embodiment is a modification of the seventh embodiment.

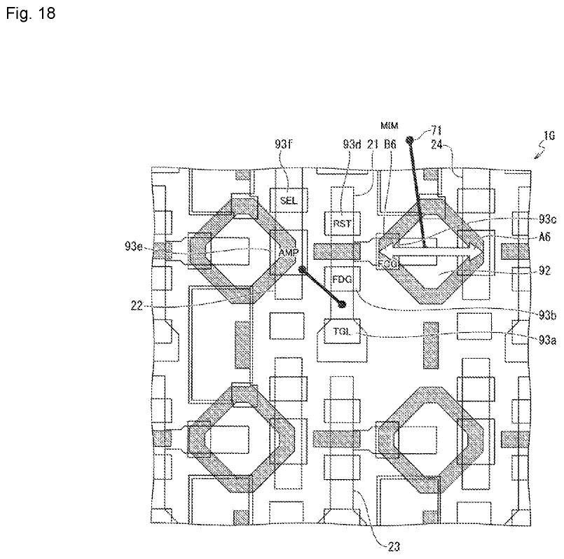

FIG. 18 is a plan view of an arrangement of pixel transistors in large-area and small-area pixels 91 and 92 in a solid-state imaging device 1G according to the eighth embodiment. In FIG. 18, the same parts as those in FIG. 4 are denoted with the same characters, and detailed description thereof will not be provided. According to the eighth embodiment, the charge storage capacitor unit 93g is a metal insulator-metal (MIM) capacitor 71. As the kind of the insulating film is varied in this way, the capacitance value can be easily increased.

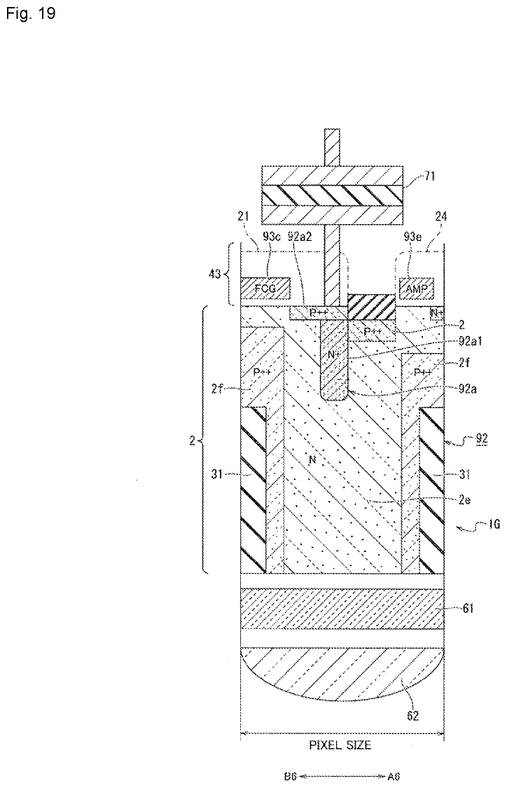

(Sectional Structure of Unit Pixel) FIG. 19 is a vertical cross section of a small-area pixel 92 in FIG. 18 taken between arrows A6 and B6 In FIG. 19, the same parts as those in FIG. 11 are denoted with the same characters, and detailed description thereof will not be provided. A metal-insulator-metal (MIM) capacitor 71 is connected to the upper part of the photodiode 92a. In order to provide a floating diffusion (FD) region and pixel transistors adjacent to a transfer gate electrode provided in the center, a high density p-type semiconductor region must be injected to isolate the n-type semiconductor region in the underlying photelectric conversion region and the n-type semiconductor region in the FD diffusion layer.

### Function and Effect According to Eighth Embodiment

As in the foregoing, according to the eighth embodiment, the charge storage capacitor unit 93g as an intra-pixel capacitor is the MIM capacitor 71, and as the kind of the insulating film is varied, the capacitance value can be easily increased.

### Ninth Embodiment

Next, a ninth embodiment will be described. The ninth embodiment is a modification of the first embodiment.

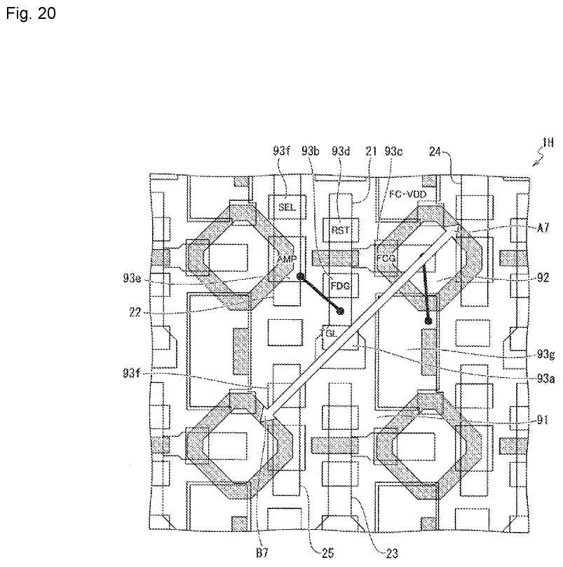

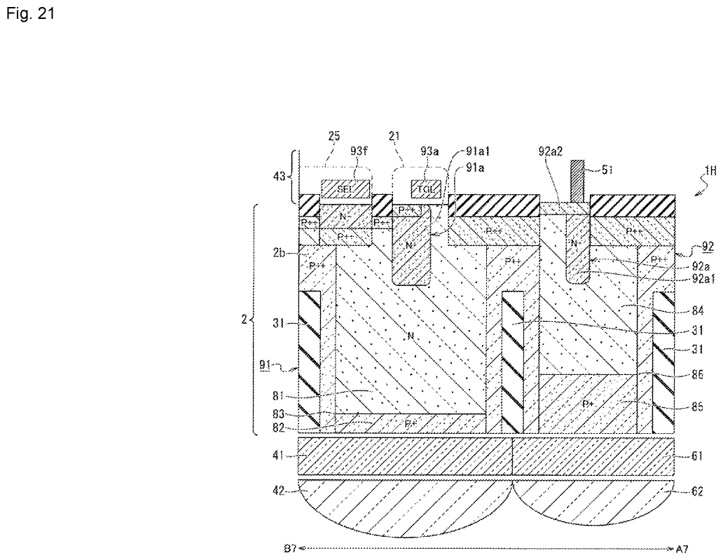

FIG. 20 is a plan view of an arrangement of pixel transistors in large-area and small-area pixels 91 and 92 in a solid-state imaging device 1H according to the ninth embodiment. FIG. 21 is a vertical cross section of large-area and small-area pixels 91 and 92 in FIG. 20 taken between arrows A7 and B7. In FIG. 20, the same parts as those in FIG. 4 are denoted with the same characters, and detailed description thereof will not be provided. In FIG. 21, the same parts as those in FIGS. 5 and 11 are denoted with the same characters, and detailed description thereof will not be provided.

According to the ninth embodiment, the large-area pixel 91 includes an n-type semiconductor region 81 and a p-type semiconductor region 82 provided to form a pn junction with the n-type semiconductor region 81. The small-area pixel 92 includes an n-type semiconductor region 84 and a p-type semiconductor region 85 provided to form a pn junction with the n-type semiconductor region 84.

The depth position 86 of the pn junction of the small-area pixel 92 is positioned closer to the side of the wiring layer 43 than the depth position 83 of the pn junction of the large-area pixel 91. The depth position 86 of the pn junction of the small-area pixel 92 is positioned closer to the light incident side than the depth end of the RDTI 31.

The depth position of the RDTI 31 is not particularly limited. The position may be changed depending on the thickness of silicon or the DTI may be an FDTI etched from the front surface side or a penetrating DTI. For any DTI, the depth position 86 of the pn junction that forms the small-area pixel 92 needs only be shallower than the depth position 83 of the pn junction of the large-area pixel 91 and deeper than the depth end of the RDTI 31.

### Function and Effect According to Ninth Embodiment

As in the foregoing, according to the ninth embodiment, for the large-area pixel 91, the p-type semiconductor region 82 can be used to pin defect levels that occur at the silicon interface at the backside surface. Accordingly, dark current can be reduced. In addition to the dark current reduction, in the small-area pixel 92, even if the high energy implantation for the depth of the n-type semiconductor region 84 is not allowed because of a finer resist shape, and depletion cannot be carried out, charge outflow to the adjacent large-area pixel 91 can be prevented by surrounding at least the neutral region with the RDTI 31.

### Tenth Embodiment

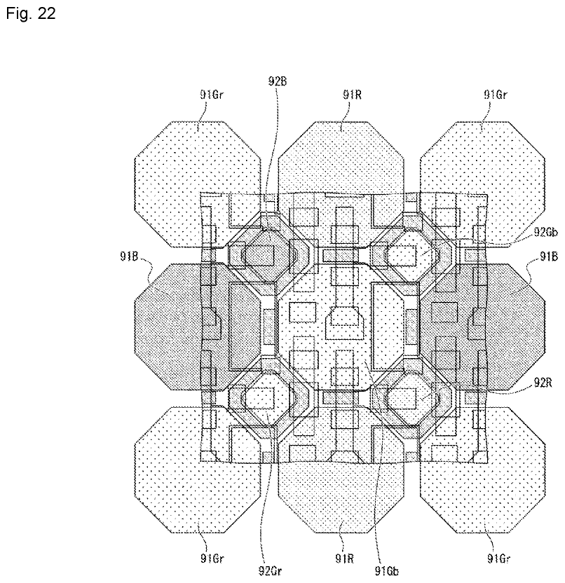

Next, a tenth embodiment will be described. FIGS. 22 to 29 are plan views for illustrating the relationship among color filter colors according to the tenth embodiment.

FIG. 22 is a plan view of RGGB type large-area and small-area pixels 91 and 92. As shown in FIG. 22, a plurality of large-area pixels 91R, 91Gr, 91B, and 91Gb are arranged in a mosaic pattern. A plurality of small-area pixels 92R, 92Gr, 92B, and 92Gb are arranged in a mosaic pattern. As schematically shown in FIG. 22, the large-area pixel 91R for red is suffixed with “R”, the large-area pixel 91B for blue is suffixed with “B”, and the large-area pixel 91Gr for reddish green is suffixed with “Gr”, and the large-area pixel 91Gb for bluish green is suffixed with “Gb”.

The color filter 41 for the large-area pixel 91R is formed corresponding to the wavelength of red light desired to be received. The color filter 41 for the large-area pixel 91R transmits light in the red light wavelength, and lets the transmitted light enter the photodiode 91a. The color filters 41 for the large-area pixels 91Gr and 91Gb transmit light in the green light wavelength, and lets the transmitted light enter the photodiode 91a. The color filter 41 for the large-area pixel 91B transmits light in the blue light wavelength, and lets the transmitted light enter the photodiode 91a.

Meanwhile, the color filter 61 for small-area pixel 92R transmits light in the red light wavelength, and lets the transmitted light enter the photodiode 92a. The color filters 61 for small-area pixels 92Gr and 92Gb transmit light in the green light wavelength, and lets the transmitted light enter the photodiode 92a. The color filter 61 for the small-area pixel 92B transmits light in the blue light wavelength, and lets the transmitted light enter the photodiode 92a.

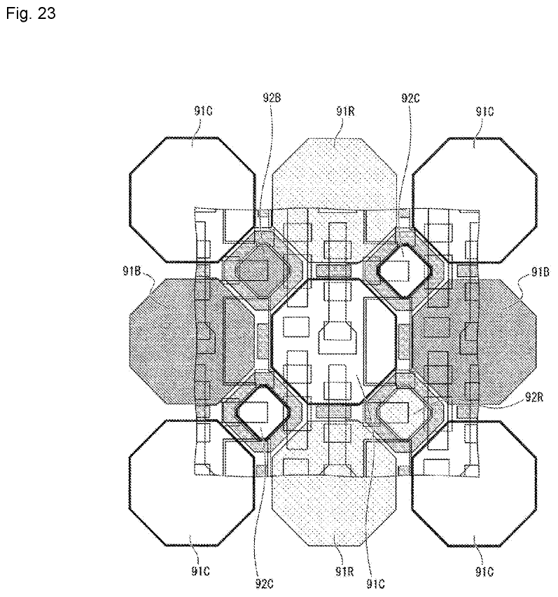

FIG. 23 is a plan view of RCCB type large-area and small-area pixels 91 and 92. As shown in FIG. 23, a plurality of large-area pixels 91R, 91C, and 91B are arranged in a mosaic pattern. A plurality of small-area pixels 92R, 92C, and 92B are also arranged in a mosaic pattern.

The color filter 41 for the large-area pixel 91C is formed corresponding to the wavelength of light desired to be received such as near-transparent light. The color filter 61 for the small-area pixel 92C is formed corresponding to the wavelength of light desired to be received such as near-transparent light.

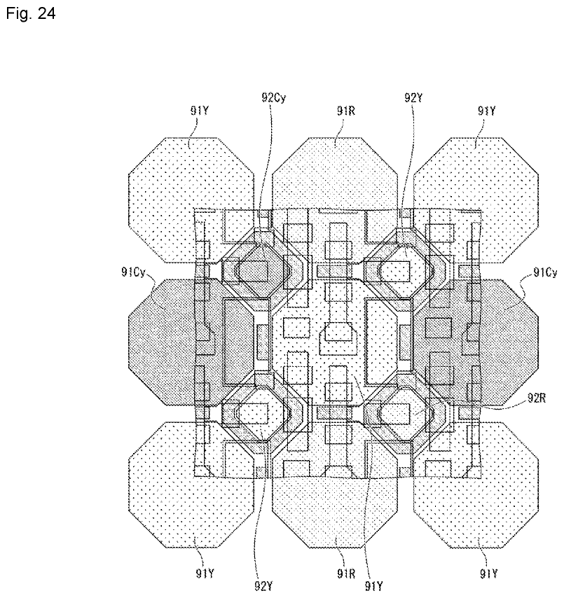

FIG. 24 is a plan view of RYYCy type large-area and small-area pixels 91 and 92. As shown in FIG. 24, a plurality of large-area pixels 91R, 91Y, and 91Cy are arranged in a mosaic pattern. A plurality of small-area pixels 92R, 92Y, and 92Cy are also arranged in a mosaic pattern.

The color filter 41 for the large-area pixel 91Y is formed corresponding to the wavelength of yellow light desired to be received. The color filter 41 for the large-area pixel 91Y transmits light in the wavelength of yellow light desired to be received, and lets the transmitted light enter the photodiode 91a.

The color filter 41 for the large-area pixel 91Cy is formed corresponding to the wavelength of cyan light desired to be received. The color filter 41 for the large-area pixel 91Cy transmits light in the wavelength of cyan light, and lets the transmitted light enter the photodiode 91a.

Meanwhile, the color filter 61 for the small-area pixel 92Y is formed corresponding to the wavelength of yellow light desired to be received. The color filter 61 for the small-area pixel 92Y transmits light in the wavelength of yellow light, and lets the transmitted light enter the photodiode 92a.

The color filter 61 for the small-area pixel 92Cy is formed corresponding to the wavelength of cyan light desired to be received. The color filter 61 for the small-area pixel 92Cy transmits light in the wavelength of cyan light, and lets the transmitted light enter the photodiode 92a.

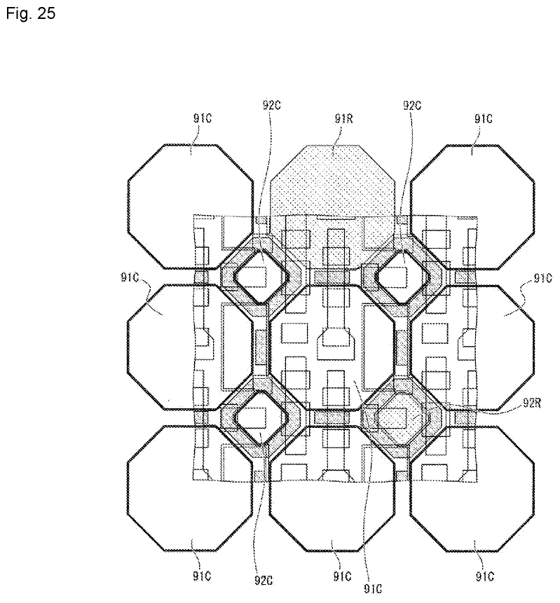

FIG. 25 is a plan view of RCCC type large-area and small-area pixels 91 and 92. As shown in FIG. 25, a plurality of large-area pixels 91R and 91C are arranged in a mosaic pattern. A plurality of small-area pixels 92R and 92C are arranged in a mosaic pattern.

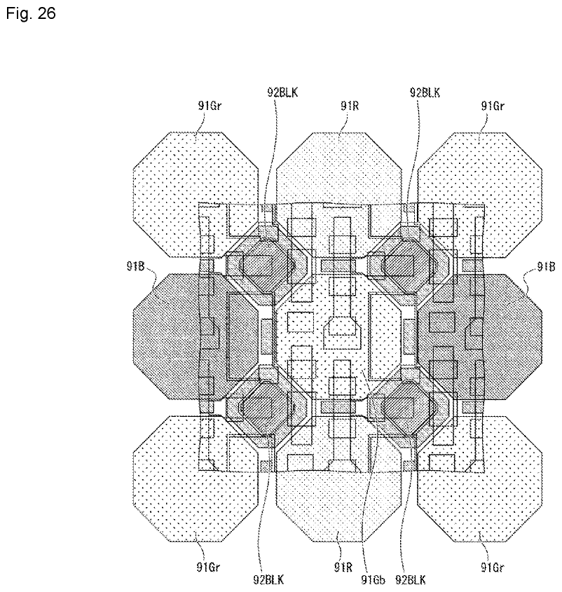

FIG. 26 is a plan view of RGB/BLK type large-area and small-area pixels 91 and 92. As shown in FIG. 26, a plurality of large-area pixels 91R, 91Gr, 91B, and 91Gb are arranged in a mosaic pattern. A plurality of small-area pixels 92BLK are arranged in a mosaic pattern.

The color filter 61 for the small-area pixel 92BLK transmits light in the wavelength of black light and lets the transmitted light enter the photodiode 92a.

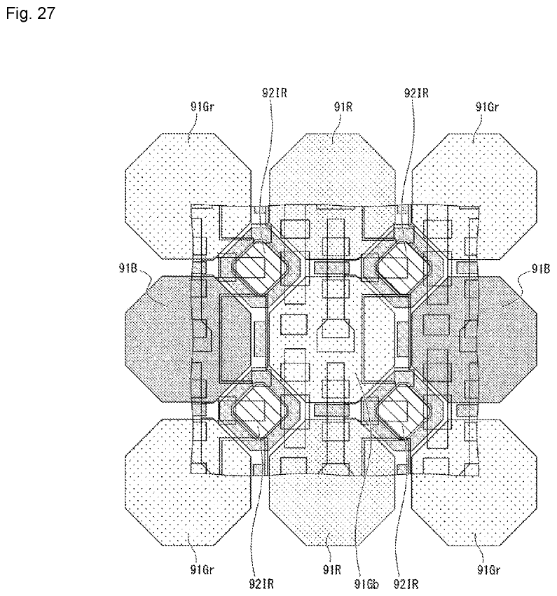

FIG. 27 is a plan view of RGB/IR type large-area and small-area pixels 91 and 92. As shown in FIG. 27, a plurality of large-area pixels 91R, 91Gr, 91B, and 91Gb are arranged in a mosaic pattern. A plurality of small-area pixels 921R are arranged in a mosaic pattern.

The color filter 61 for the small-area pixel 92IR transmits light in the wavelength of infrared light and lets the light enter the photodiode 92a. The color filter 61 for the small-area pixel 92IR is formed corresponding to the wavelength of infrared light desired to be received.

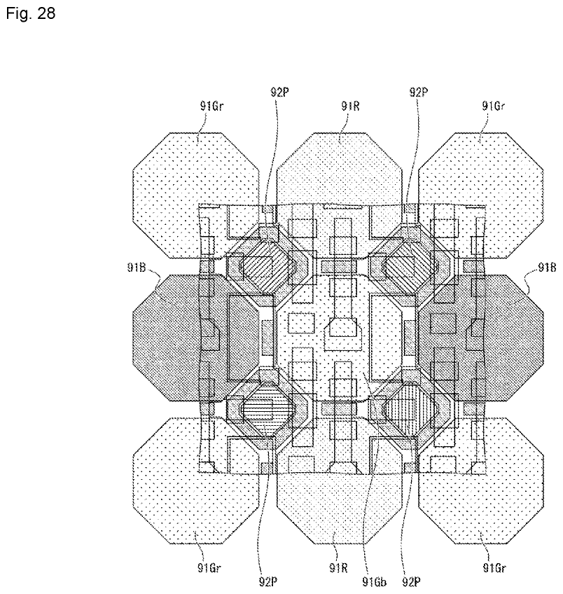

FIG. 28 is a plan view of RGB/polarizing type large-area and small-area pixels 91 and 92. As shown in FIG. 28, a plurality of large-area pixels 91R, 91Gr, 91B, and 91Gb are arranged in a mosaic pattern. A plurality of small-area pixels 92P are arranged in a mosaic pattern.

The color filter 61 for the small-area pixel 92P polarizes light desired to be received and lets the light enter the photodiode 92a.

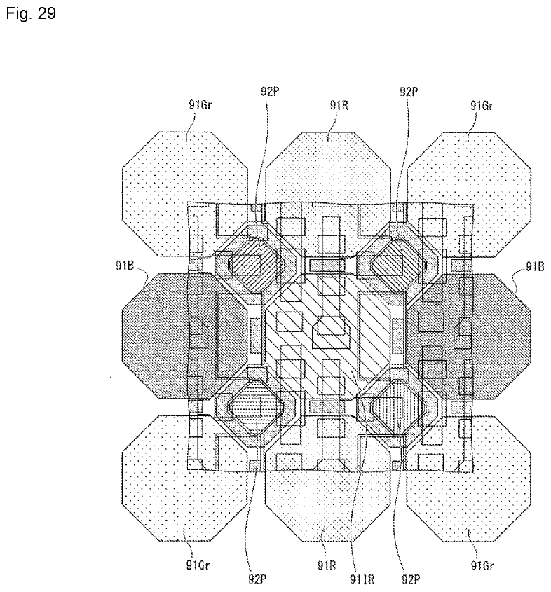

FIG. 29 is a plan view of RGB/polarizing/IR type large-area and small-area pixel 91 and 92. As shown in FIG. 29, a plurality of large-area pixels 91R, 91Gr, 91B, 91Gb, and 91IR are arranged in a mosaic pattern. A plurality of small-area pixels 92P are arranged in a mosaic pattern.

The color filter 41 for the large-area pixel 91IR is formed corresponding to the wavelength of infrared light desired to be received. The color filter 41 for large-area pixel 91IR transmits light in the infrared wavelength, and lets the transmitted light enter the photodiode 91a.

Note that the colors of the color filters 41 and 61 are not particularly limited and the kinds of color are not limited. Color combinations among the large-area pixels 91 and the small-area pixels 92 are not limited. The IR or polarization at the small-area pixel 92 needs only be present at a part of the array arrangement.

### Other Embodiments

As in the foregoing, the present disclosure has been described with reference to the first to tenth embodiments, but the description and drawings that form a part of the present disclosure should not be construed as limiting the features. It is to be understood that various alternative embodiments, embodiments, and operation features will be apparent to those skilled in the art from the gist of the technical content disclosed according to the first to tenth embodiments. The disclosed features according to the first to tenth embodiments may be combined as appropriate so that no contradictions arise. For example, the disclosed features according to multiple different embodiments may be combined and features according to multiple different modifications of the same embodiment may be combined.

<Exemplary Application to Electronic Device>

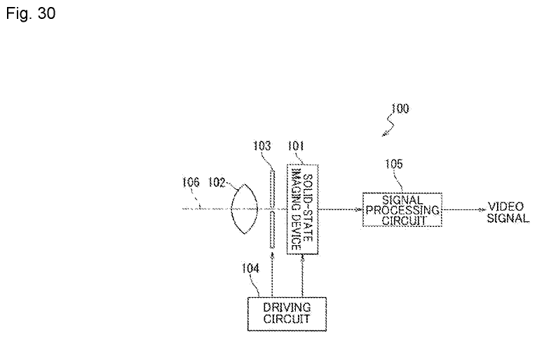

Next, an electronic device according to an eleventh embodiment of the present disclosure will be described. FIG. 30 is a schematic diagram of an electronic device 100 according to the eleventh embodiment of the present disclosure.

The electronic device 100 according to the eleventh embodiment includes a solid-state imaging device 101, an optical lens 102, a shutter device 103, a driving circuit 104, and a signal processing circuit 105. According to the eleventh embodiment, the solid-state imaging device 1 according to the first embodiment of the present disclosure is used as the solid-state imaging device 101 for the electronic device 100 (such as a camera).

The optical lens 102 forms an image based on image light (incident light 106) from an object on the imaging surface of the solid-state imaging device 101. In this way, signal charge is stored for a fixed time period in the solid-state imaging device 101. The shutter device 103 controls the light irradiation period and light-shielding period to the solid-state imaging device 101. The driving circuit 104 supplies drive signals that control the transfer operation of the solid-state imaging device 101 and the shutter operation of the shutter device 103. The drive signal (timing signal) supplied by the driving circuit 104 controls the signal transfer of the solid-state imaging device 101. The signal processing circuit 105 performs various kinds of signal processing on signals (pixel signals) output from the solid-state imaging device 101. A video signal having been subjected to signal processing is stored at a storage medium such as a memory or output to a monitor.

In this way, the electronic device 100 according to the eleventh embodiment allows optical color mixing to be reduced in the solid-state imaging device 101, so that the image quality of video signals can be improved.

Note that the electronic device 100 for which the solid-state imaging devices 1, 1A, 1B, 1C, 1D, 1E, 1F, 1G, or 1H can be used is not limited to a camera, and the solid-state imaging device can also be used for any of other electronic devices. For example, the solid-state imaging device may be used for an imaging device such as a camera module for a mobile device such as a mobile phone.

Also according to the eleventh embodiment, any of the solid-state imaging devices 1, 1A, 1B, 1C, 1D, 1E, 1F, 1G, and 1H according to the first to tenth embodiments is used as the solid-state imaging device 101 for an electronic device, but other configurations may be used.

The present disclosure can also be configured as follows.

(1)

A solid-state imaging device comprising a plurality of unit pixels arranged in a two-dimensional array, the plurality of unit pixels each comprising:

a photoelectric conversion unit that photoelectrically converts incident light; and

a wiring layer stacked on a surface opposite to a light-incident side surface of the photoelectric conversion unit and having a detection node that detects charge stored at the photoelectric conversion unit,

wherein

in at least some of the plurality of unit pixels,

a center of the detection node is substantially coincident with a light receiving center of the photoelectric conversion unit.

(2)

The solid-state imaging device according to (1), wherein the plurality of unit pixels comprises a large-area pixel and a small-area pixel, and

in both or one of the large-area pixel and the small-area pixel, the center of the detection node is substantially coincident with the light receiving center of the photoelectric conversion unit.

(3)

The solid-state imaging device according to (1) or (2), wherein the detection node is a planar type node.

(4)

The solid-state imaging device according to (1) or (2), wherein the detection node is a vertical transistor.

(5)

The solid-state imaging device according to (1) or (2), wherein the detection node is a directly connecting type node.

(6)

The solid-state imaging device according to (1) or (2), wherein the wiring layer has a charge storage unit that stores charge generated by the photoelectric conversion unit.

(7)

The solid-state imaging device according to (1) or (2), wherein the wiring layer has a pixel transistor that performs signal processing on charge output from the photoelectric conversion unit.

(8)

The solid-state imaging device according to (1) or (2), wherein the wiring layer has an intra-pixel capacitor.

(9)

The solid-state imaging device according to (8), wherein the intra-pixel capacitor is a metal-insulator-metal (MIM) capacitor.

(10)

The solid-state imaging device according to (2), wherein the photoelectric conversion unit has a first electrode region of a first conductivity type, and a second electrode region of a second conductivity type provided to form a pn junction with the first electrode region, and

the depth position of the pn junction of the small-area pixel is located closer to the wiring layer side than the depth position of the pn junction of the large-area pixel.

(11)

The solid-state imaging device according to (10), further comprising an inter-pixel light-shielding part that insulates and light-shields between the small-area pixel and the large-area pixel, wherein

the depth position of the pn junction of the small-area pixel is located closer to the wiring layer side than the depth position of the pn-junction of the large-area pixel and closer to the light-incident side than the depth end of the inter-pixel light-shielding part.

(12)

The solid-state imaging device according to (1), wherein at least some of the plurality of unit pixels comprise a color filter corresponding to a different light wavelength and provided on the light-incident side of the photoelectric conversion unit.

(13)

The solid-state imaging device according to (1), wherein the center of the detection node includes a transfer gate electrode for transferring charge stored at the photoelectric conversion unit.

(14)

The solid-state imaging device according to (1), wherein the center of the detection node includes metal.

(15)

An electronic device comprising a solid-state imaging device, the solid-state imaging device including a plurality of unit pixels arranged in a two-dimensional array,

the plurality of unit pixels each including:

a photoelectric conversion unit that photoelectrically converts incident light; and

a wiring layer stacked on a surface opposite to a light-incident side surface of the photoelectric conversion unit and having a detection node that detects charge stored at the photoelectric conversion unit,

wherein

in at least some of the plurality of unit pixels,

a center of the detection node is substantially coincident with a light receiving center of the photoelectric conversion unit.

[Reference Signs List]

| 1A, 1B, 1C, 1E, 1F, 1G, 1H | Solid-state imaging device |
|---|---|
| 2 | Substrate |
| 2a, 2d, 2e, 2h, 81, 84, | N-type semiconductor region |
| 91a1, 92a1 | |
| 2b, 2c, 2f, 2g, 82, 85, | P-type semiconductor region |
| 91a2, 92a2 | |
| 3 | Pixel region |
| 4 | Vertical driving circuit |
| 5 | Column signal processing |
| | circuit |
| 6 | Horizontal driving circuit |
| 7 | Output circuit |
| 8 | Control circuit |
| 9 | Unit pixel |
| 10 | Pixel driving wiring |
| 11 | Vertical signal line |
| 12 | Horizontal signal line |
| 21, 22, 23, 24 | Wiring |
| 41, 61 | Color filter |
| 42, 62 | On-chip lens |
| 43 | Wiring layer |
| 51 | Metal |
| 70 | MIM (Metal-Insulator-Metal) |
| | capacitor |
| 86 | Position |
| 91 | Large-area pixel |
| 91a, 92a | Photodiode |
| 91B, 91C, 91Cy, 91Gr, | Large-area pixel |
| 91Gb, 91IR, 91R, 91Y | |
| 92, 92B, 92BLK, 92C, | Small-areapixel |
| 92Cy, 92Gb, 92Gr, 92IR, | |
| 92P, 92R, 92Y | |
| 93a, 93a1, 93a2, 93i, 93i1 | Transfer transistor |
| 93b, 93c | Conversion efficiency |
| | adjustment transistor |
| 93d | Reset transistor |
| 93e | Amplification transistor |
| 93f | Selection transistor |
| 93g | Charge storage capacitor unit |
| 93h, 93j | Charge storage unit |
| 100 | Electronic device |
| 101 | Solid-state imaging device |
| 102 | Optical lens |
| 103 | Shutter device |
| 104 | Driving circuit |
| 105 | Signal processing circuit |
| 106 | Incident light |

1. A solid-state imaging device comprising a plurality of unit pixels arranged in a two-dimensional array,
the plurality of unit pixels each comprising:
a photoelectric conversion unit that photoelectrically converts incident light; and
a wiring layer stacked on a surface opposite to a light-incident side surface of the photoelectric conversion unit and having a detection node that detects charge stored at the photoelectric conversion unit,
wherein
in at least some of the plurality of unit pixels,
a center of the detection node is substantially coincident with a light receiving center of the photoelectric conversion unit.

2. The solid-state imaging device according to claim 1, wherein the plurality of unit pixels comprises a large-area pixel and a small-area pixel, and
in both or one of the large-area pixel and the small-area pixel,
the center of the detection node is substantially coincident with the light receiving center of the photoelectric conversion unit.

3. The solid-state imaging device according to claim 1, wherein the detection node is a planar type node.

4. The solid-state imaging device according to claim 1, wherein the detection node is a vertical transistor.

5. The solid-state imaging device according to claim 1, wherein the detection node is a directly connecting type node.

6. The solid-state imaging device according to claim 1, wherein the wiring layer has a charge storage unit that stores charge generated by the photoelectric conversion unit.

7. The solid-state imaging device according to claim 1, wherein the wiring layer has a pixel transistor that performs signal processing on charge output from the photoelectric conversion unit.

8. The solid-state imaging device according to claim 1, wherein the wiring layer has an intra-pixel capacitor.

9. The solid-state imaging device according to claim 8, wherein the intra-pixel capacitor is a metal-insulator-metal (MIM) capacitor.

10. The solid-state imaging device according to claim 2, wherein the photoelectric conversion unit has a first electrode region of a first conductivity type, and a second electrode region of a second conductivity type provided to form a pn junction with the first electrode region, and
the depth position of the pn junction of the small-area pixel is located closer to the wiring layer side than the depth position of the pn junction of the large-area pixel.

11. The solid-state imaging device according to claim 10, further comprising an inter-pixel light-shielding part that insulates and light-shields between the small-area pixel and the large-area pixel, wherein
the depth position of the pn junction of the small-area pixel is located closer to the wiring layer side than the depth position of the pn-junction of the large-area pixel and closer to the light-incident side than the depth end of the inter-pixel light-shielding part.

12. The solid-state imaging device according to claim 1, wherein at least some of the plurality of unit pixels comprise a color filter corresponding to a different light wavelength and provided on the light-incident side of the photoelectric conversion unit.

13. The solid-state imaging device according to claim 1, wherein the center of the detection node includes a transfer gate electrode for transferring charge stored at the photoelectric conversion unit.

14. The solid-state imaging device according to claim 1, wherein the center of the detection node includes metal.

15. An electronic device comprising a solid-state imaging device,
the solid-state imaging device including a plurality of unit pixels arranged in a two-dimensional array,
the plurality of unit pixels each including:
a photoelectric conversion unit that photoelectrically converts incident light; and
a wiring layer stacked on a surface opposite to a light-incident side surface of the photoelectric conversion unit and having a detection node that detects charge stored at the photoelectric conversion unit,
wherein
in at least some of the plurality of unit pixels,
a center of the detection node is substantially coincident with a light receiving center of the photoelectric conversion unit.
